(19) United States
(12) Patent Application Publication
(10) Pub. No.: US 2015/0107645 A1
(43) Pub. Date: Apr. 23, 2015

(54) SOLAR CELL

(71) Applicant: SolarWorld Innovations GmbH, Freiberg (DE)

(72) Inventor: Bernd Bitnar, Bannewitz (DE)

(21) Appl. No.: 14/488,303

(22) Filed: Sep. 17, 2014

(30) Foreign Application Priority Data
Oct. 22, 2013 (DE) 102013111634.5

(51) Int. Cl. H01L 31/02; H01L 31/05

(52) U.S. Cl. CPC H01L 31/0201; H01L 31/0508
USPC 136/244; 136/256

(57) ABSTRACT

In various embodiments, a solar cell includes: a substrate with a light incidence side and a rear side and a dielectric layer on the back of the substrate. The dielectric layer includes openings, which extend through the dielectric layer towards the back of the substrate. The solar cell further includes a plurality of metal contacts which are configured in the openings; and a metal structure which is configured on the dielectric layer. The metal structure includes contact areas which are connected to the metal contacts in an electrically conducting manner. The metal structure is structured such that the dielectric layer is at least partially exposed around the metal contacts.

### CROSS-REFERENCE TO RELATED APPLICATION

This application claims priority to German Patent Application Serial No. 10 2013 111 634.5, which was filed Oct. 22, 2013, and is incorporated herein by reference in its entirety.

### TECHNICAL FIELD

Various embodiments relate generally to a solar cell.

### BACKGROUND

Conventionally, a solar cell has a first electrode, a second electrode and an optically active area on a silicon substrate, wherein the optically active area is equipped to convert an electromagnetic radiation into an electrical current and is electrically configured between the first electrode and the second electrode. Further, a conventional solar cell has a rear metallization contact. The rear metallization contact is electrically connected to the second electrode. The rear metallization contact is not completely configured in the PERC solar cell (so-called passivated emitter and rear cell—PERC). In this case, the rear metallization contact normally has a metallization coating on a dielectric passivation coating. The rear metallization coating is normally deposited completely over the back of the Silicon substrate in order to collect the electric current generated from the solar cell. Often, this rear metallization coating is made of aluminum. Local contact openings (so-called local contact openings) are configured in the dielectric layer, in which electrical interlayer connections are normally configured. The electrical interlayer connections connect the silicon substrate with the metallization coating. The local contact openings are normally configured by means of a Laser ablation process. The metallization coating and the interlayer connections are configured by means of screen printing of a screen printed paste and a subsequent melting (burning) of the screen printed paste.

The local rear metallization contacts of PERC solar cells are limited, inter alia, by the problem of the so-called cavity formation (void formation). Normally, there are cavities on the ablated areas of the dielectric layer under the aluminum metallization coating, in which partially no rear side field (so-called back surface field—BSF) is configured. An established theory for cavity formation describes the diffusion of silicon from the silicon substrate into aluminum of the aluminum metallization coating at the start of the burning step of the aluminum containing screen printed paste. Die aluminum screen printed paste surrounding the opened areas of the dielectric layer can completely diffuse the silicon.

The solubility limit of silicon in aluminum is not achieved in conventional PERC solar cells, so that the diffusion of silicon into aluminum can proceed indefinitely. A trench, several micron (μm) deep thus forms, which is initially filled with silicon-enriched aluminum. During the end phase of the burning, the aluminum/silicon-melt dissolves from the trench, whereby a cavity is formed in the trench.

The cavity formation is accepted in a conventional PERC process with an aluminum printing step.

In another conventional PERC process, the metallization contact is configured by means of a double aluminum printing. Here, initially a line pattern is printed on the ablated area in the dielectric layer, this is burned and subsequently a second aluminum printing is done. However, this process is more complex and more time and cost-intensive in comparison to the standard PERC process.

### SUMMARY

In various embodiments, a solar cell includes: a substrate with a light incidence side and a rear side and a dielectric layer on the back of the substrate. The dielectric layer includes openings, which extend through the dielectric layer towards the back of the substrate. The solar cell further includes a plurality of metal contacts which are configured in the openings; and a metal structure which is configured on the dielectric layer. The metal structure includes contact areas which are connected to the metal contacts in an electrically conducting manner. The metal structure is structured such that the dielectric layer is at least partially exposed around the metal contacts.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B show schematic representations of a rear side of a solar cell according to different embodiments;

FIGS. 2A and 2B show cross-sectional views of a part of a solar cell according to different embodiments (FIG. 2A) and a conventional PERC solar cell (FIG. 2B);

FIGS. 3A and 3B show a rear view (FIG. 3A) and a cross-sectional view (FIG. 3B) of a part of a solar cell according to different embodiments; and

FIGS. 4A and 4B show a rear view (FIG. 4A) and a cross-sectional view (FIG. 4B) of a part of a solar cell according to different embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

A reference will be made to the accompanying drawing in the following detailed description, which forms a part of this and in which, specific embodiments are shown for illustration, in which the invention can be exercised. In this regard, the directional terminology such as “above”, “below”, “in front”, “behind”, “forward”, “rearward”, etc. are used with reference to the orientation of the described figure(s). Since components of embodiments can be positioned in a number of different orientations, the directional terminology is used for illustration and is not limited in any way. It is obvious that other embodiments can be used and structural or logical changes can be undertaken without departing from the scope of protection of the present invention. It must be understood that the features of the different embodiments described here can be combined with each other, unless specifically stated otherwise. Therefore, the following detailed description is not to be understood in a restrictive sense, and the scope of protection of the present invention is defined by the appended claims.

Within the scope of this description, the terms “connected”, “attached” and “coupled” are used for describing a direct as well as an indirect connection, a direct or indirect attachment, as well as a direct or indirect coupling. Identical or similar elements are provided with identical reference numerals in the figures, wherever appropriate.

A solar cell is provided in different embodiments, by which it is possible to reduce the diffusion of Silicon into surrounding aluminum. Furthermore, series resistance losses in solar cells can be reduced by preventing cavity formation.

In different embodiments, a solar cell can have a silicon solar cell, for example a PERC solar cell, i.e. a solar cell in the form of a passivated emitter and a rear cell (so-called passivated emitter and rear cell) or a locally diffused, passivated rear solar cell (passivated rear locally diffused cell—PERL).

A solar cell is provided in different embodiments. The solar cell may have: a substrate with a light incidence side and a rear side; a dielectric layer on the back of the substrate, wherein the dielectric layer has openings, which extend through the dielectric layer towards the back of the substrate; a number of metal contacts which are configured in the openings; and a metal structure which is configured on the dielectric layer. The metal structure has contact areas which are connected to the metal contacts in an electrically conducting manner. Further, the metal structure is structured such that the dielectric layer is at least partially exposed around the metal contacts.

The openings can be configured as local contact openings in the dielectric layer. In one configuration, the openings may have at least one of the following shapes (in top view): an arrangement of several contact openings (in a regular or irregular pattern), an arrangement of several contact line openings (in a regular or irregular pattern). Contact line openings may also be designated as linear contact openings.

In one configuration, the metal structure may have silver and/or aluminum; and/or the number of metal contacts may have aluminum.

In still another configuration, the metal structure can have several metal wires, which are connected to the metal contacts in an electrically conducting manner.

In yet another configuration, the metal wires may have copper.

In still another configuration, the metal structure may have several busbars, which are connected to the metal contacts in an electrically conducting manner.

In yet another configuration, the contact areas may be configured such that the lateral expansion of a respective metal contact is substantially limited to the lateral expansion of an associated opening.

In still another configuration, the exposed areas of the dielectric layer laterally surround the openings.

In yet another configuration, the metal structure may have an electrically conducting connection structure, which extends on the exposed areas of the dielectric layer up to the electrically conducting connection of the metal contacts with a metallic coating of the metal structure.

In still another configuration, the electrically conducting connection structure may have a grid-like structure.

In yet another configuration, the electrically conducting connection structure may have the same material as the metal structure or the number of metal contacts.

In still another configuration, the electrically conducting connection structure can have one or more metals, for example—one or more of the following metals: aluminum, silver, copper, zinc, and/or gold.

In yet another configuration, the metal structure may have a metallic coating.

In still another configuration, the metallic coating may be a screen-printed coating.

In one configuration, the metal contacts may have or be molten electrically conducting structures, for example, configured from a screen-printed paste molten in a burning process.

The exposed areas of the dielectric layer may be free from a physical contact with the metallic coating. The exposed areas of the dielectric layer may laterally surround the openings. Further, the exposed areas of the dielectric layer may be exposed by means of a Laser ablation process.

In yet another configuration, the solar cell may further have a diffusion bather between the substrate and the electrically conducting material, such that an inter-diffusion of the materials of the substrate and electrically conducting material is reduced with respect to a contact without diffusion bather. The diffusion bather can have a metallic oxide or can be made therefrom.

Furthermore, a solar module is provided with several solar cells, which are interconnected in an electrically conducting manner, for example by means of cell connectors. The solar cells can be configured in a manner as described above or as described in the following.

In various embodiments, a solar cell may have a first electrode structure, a second electrode structure and an optically active area between the first electrode structure and the second electrode structure.

The first electrode structure can be configured directly on the optically active area, i.e. on the front side, in the path of the radiation of an optically active area to an electromagnetic radiation converted into an electrical voltage and/or an electrical current. For example, the first electrode structure can be configured as front side contact or front side metallization. The front side contact can be configured structured over the optically active area, for example, finger-shaped as metallization or in the form of a selective emitter or as a combination of both. A structured configured front side metallization can be configured, for example, essentially (except for electrical cross-links) only on the optically active area.

The optically active area of the solar cell can have an electrically conducting and/or semiconducting material, for example—a doped silicon, for example, p-doped (p-type), for example—with a doping of boron, gallium and/or indium; or n-doped (n-type), for example, with a doping of phosphorus, arsenic and/or antimony. Other suitable dopants can similarly be provided in various embodiments.

The optically active area can absorb electromagnetic radiation and form a photocurrent therefrom. The electromagnetic radiation can have a range of wavelengths, which includes X-rays, UV-radiation (A to C), visible light and/or Infrared-radiation (A to C).

The optically active area can have a first area which is doped with a different type of dopant than the second area and remains in bodily contact with this. For example, the first area can be a p-type (doped with p-dopant(s)) and the second area can be an n-type (doped with n-dopant(s)), and vice-versa. A pn-junction can be configured at the interface of the first area with the second area, whereupon electron-hole-pairs can be generated. The optically active area can have several pn-junctions, for example, next to each other and/or on top of each other.

A rear contact structure can be configured on the shaded side of the solar cell. The rear contact structure can have the second electrode structure or can be configured on the second electrode structure. Furthermore, the rear contact structure can have a dielectric layer. The dielectric layer can have one or more dielectric layers on the second electrode structure and/or between the optically active area and the second electrode structure. Furthermore, the rear contact structure can have an electrically conducting coating, which can be configured on the dielectric layer. The electrically conducting coating can be configured as the second electrode structure and/or can be electrically connected to this.

The dielectric layer can have one or more openings. Metal contacts can be configured in the openings. The metal contacts can be configured as electrically conducting areas in the dielectric layer, such that a continuous electrically conducting connection to the substrate is configured through the dielectric layer, for example, to the optically active area of the solar cell. For example, the metal contacts can have the same material or can be formed from the same material as the second electrode structure, for example, a noble metal, semiconducting metal, Graphene, Graphite and/or Carbon nanotubes. The openings can be so-called contact openings (e.g. so called local contact openings—LCO).

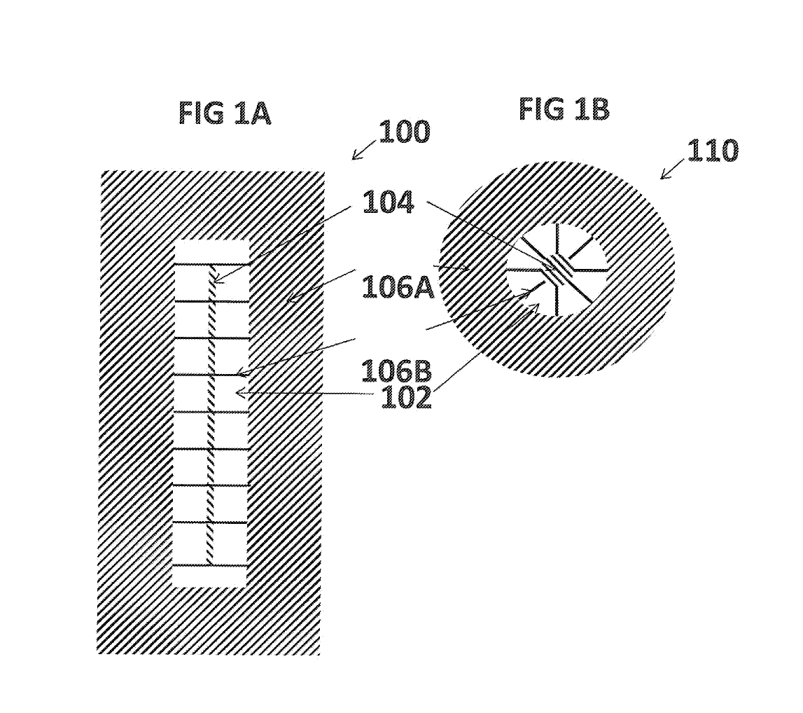

FIG. 1 to FIG. 4 shall illustrate embodiments of sections from a rear metallization layout of a solar cell.

FIG. 1A shows a rear view 100 of a solar cell according to various embodiments. FIG. 1B shows another rear view 110 of a solar cell according to other embodiments.

As shown in FIG. 1A, a dielectric layer 102 is provided on the rear side of the solar cell, as explained in more details in the following, which is partially covered by a metal structure. The metal structure can have contact areas 106B. In various embodiments, the metal structure can have a metallic coating or several metallic coatings, which is applied on or via the dielectric layer 102. For example, the metallic coating can have aluminum, silver or zinc or can be formed therefrom. The metallic coating can be structured such that the metallic coating and thereby the metal structure has a number of contact areas 106B, which connect, for example, the flat partial areas 106A of the metallic coating with metal contacts 104 in an electrically conducting manner, as they are explained in more details in the following. The metallic coating can be a screen-printed coating.

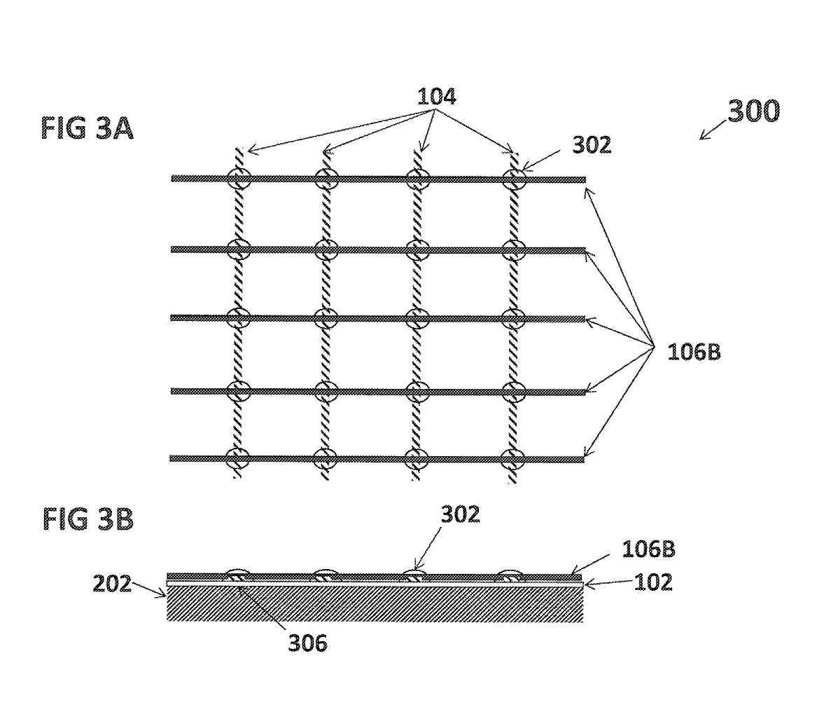

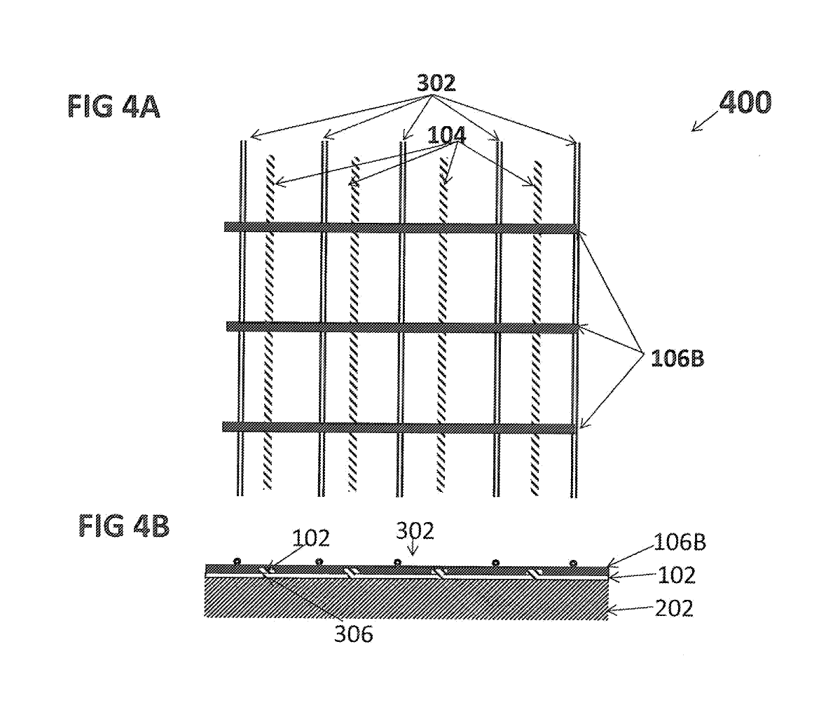

The dielectric layer 102 can have openings 306, for example, illustrated in FIG. 3B and FIG. 4B. The openings 306 can be configured in the dielectric layer 102 as local contact openings 306. The openings 306 can have at least one of the following shapes (in top view): an arrangement of several contact openings 306 (in a regular or irregular pattern), and/or an arrangement of contact line openings 306 (in a regular or irregular pattern).

The openings 306 can have an average (lateral) width in a range of approximately 20 μm to approximately 100 μm and the dielectric layer 102 can have a layer thickness in a range of approximately 0.03 μm to approximately 5 μm.

The openings 306 can at least partially be filled with at least one electrically conductive material (also designated as electrically conducting material) 104, for example, with one or several metals. The openings 306 can at least partially be filled with electrically conducting material 104. The electrically conducting material 104 can have the same material as the metallic layer or can be made therefrom. The electrically conducting material 104 can preferably have aluminum. The electrically conducting material 104 clearly makes metal contacts 104 in the openings 306. The electrically conducting material 104 can be configured in the form of electrical interlayer connections (also designated as Vias) through the dielectric layer 102.

In various embodiments, the openings 306 can have two or more materials other than the electrically conducting filling, wherein the two or more other materials can have different electrical conductivities, different diffusion characteristics with respect to one material and/or different wetting properties with respect to the substrate and/or another material applied on the material. For example, the filling of the opening can have: aluminum; aluminum and silver. The two or more other materials of the filling can be configured in the opening next to each other, on top of each other and/or concentrically with respect to each other.

The contact areas 106B can be connected to the metal contacts 104 in an electrically conducting manner.

The metal contacts 104 can have at least one of the following shapes: a number of contact points (in a regular or irregular pattern), a number of contact lines (in a regular or irregular pattern).

The metal contacts 104 can be configured such that the lateral expansion of a metal contact 104 is substantially limited to the lateral expansion of the opening 306.

The metal contacts 104 can have or can be molten electrically conducting structures.

In various embodiments, a metal contact 104 can have a lateral width in a range of approximately 10 μm to approximately 150 μm and a thickness in a range of approximately 10 μm to approximately 100 μm.

In an embodiment, the linear metal contacts 104 can clearly be configured in a similar manner as the finger-shaped structure of the first electrode structure of the solar cell (expressed otherwise as the contact finger on the light incidence side of the solar cell), for example, parallel, plano-parallel and/or congruent.

The metallic coating can be configured such that the dielectric layer 102 is at least partially exposed around the metal contacts 104—illustrated in FIG. 1A and FIG. 1B.

The exposed areas of the dielectric layer 102 can laterally surround the openings 306. The exposed areas of the dielectric layer 102 can be exposed by means of a Laser ablation process.

In various embodiments, an exposed area of the dielectric layer 102 can have a lateral dimension (width), which is smaller than approximately 1 mm.

In various embodiments, the metal structure can have an electrically conducting connection structure 106A, 106B. The connection structure 106A, 106B can be configured, at least electrically coupled with a part of the metal contacts 104. The connection structure 106A, 106B can be electrically conductive. In various embodiments, the connection structure 106A, 106B can have one of the following shapes: an arrangement of connection lines 106B, for example, in the form of bridges or webs, for example, a connection grid (illustrated in FIG. 3A and FIG. 4A). In an embodiment, the connection structure 106A, 106B can have at least one electrically conducting wire or can be configured therefrom (illustrated in FIG. 3A and FIG. 4A).

The connection structure 106A, 106B can be configured on or via the dielectric layer 102. The connection structure 106A, 106B can be configured such that the metal contacts 104 can be interconnected by means of the connection structure 106A, 106B at least partially in an electrically conducting manner. The connection structure 106A, 106B can have the same material or can be formed therefrom, as at least a part of the metal contacts 104 and/or of a metallic coating of the metal structure.

In an embodiment, the connection structure 106A, 106B and at least a part of the metal contacts 104 can be configured as a coating, i.e. as a single, continuous coating, for example, by means of a screen printing by a structured screen. In various embodiments, the connection structure 106A, 106B and at least a part of the metal contacts 104 can clearly be applied in a common process step.

The connection structure 106A, 106B can have one of the following materials or can be made therefrom: aluminum, silver, copper, gold, and/or zinc.

In various embodiments, the connection structure 106A, 106B can have a linear structure 106B, wherein the linear structure 106B can have a lateral width in a range of approximately 30 μm to approximately 100 μm and a coating thickness in a range of approximately 5 μm to approximately 15 μm. In an embodiment, the linear structures 106B can be configured analogous to a finger-shaped structure of the first electrode structure of the solar cell, for example, parallel, plano-parallel and/or congruent.

In an embodiment, an opening 306 of the dielectric layer 102 can be configured for making a respective metal contact 104, such that the metal contact 104 is configured in the form of a point contact (illustrated in FIG. 1B) and/or of a line contact (illustrated in FIG. 1A).

In an embodiment, the dielectric layer 104 is configured structured, such that it has openings 306, for example, a Laser ablation process can advantageously be employed. For example, the dielectric layer 104 can be configured structured by means of a masking process, for example, by means of a screen printing process.

The openings 306 can clearly be configured under the metal structure (for example, illustrated in FIG. 3B and FIG. 4B).

For example, the metal structure can be configured by means of a printing of an aluminum paste. The aluminum paste can be applied by means of a structured screen, for example, completely on the screen, so that the aluminum paste is applied on the printed substrate only in the structured areas of the screen. In the exposed, for example, opened, for example, ablated, areas of the dielectric layer 104, the printed aluminum paste can locally form the metal contacts 104, with respect to the ablated exposed areas.

As it has been described above, the connection structure 106A, 106B can be configured in the metal structure. This can have—for example, in the vicinity of the openings 306 of the dielectric layer 102, i.e. in the vicinity of the metal contacts 104—a smaller, for example, linear shape (illustrated in FIG. 1A and FIG. 1B by means of the reference numeral 106B) than in the areas (illustrated in FIG. 1A and FIG. 1B by means of the reference numerals 106A) distant from the openings 306. For example, the more distant portion of the connection structure 106A, 106B can be configured as flat connection structure 106A. The linear portion 106B of the connection structure 106A, 106B can diffuse silicon to reduce the material cross-section in the vicinity of the openings 306, for example, in order to reduce the amount of silicon which could dissolve in aluminum during burning of the aluminum paste. Thereby, the cavity formation can be reduced.

The distant portion 106A of the connection structure 106A, 106B can increase the lateral power distribution, since it has a larger surface of electrically conductive material than the area of the connection structure 106B in the vicinity of the openings 306. The metal structure 106A, 106B can be configured structured on the dielectric layer 102, such that a topographically structured surface with electrically conducting areas and electrically non-conducting areas is configured.

For example, the linear portion of the connection structure 106A, 106B can be configured as narrow electrically conducting bridges. In an embodiment, the linear portion of the connection structure 106A, 106B can be configured from aluminum or from silver and the flat portion 106A of the connection structure 106A, 106B from aluminum. The connection structure 106B can be made of a material with a higher conductivity than that of the material of the connection structure 106A. For example, the connection structure 106B can be configured from Silver and the connection structure 106A can be configured from aluminum.

In an embodiment, the metal structure can include aluminum or made therefrom. In an embodiment, the metal contacts 104 and the connection structure 106A, 106B can be configured in a common aluminum printing step.

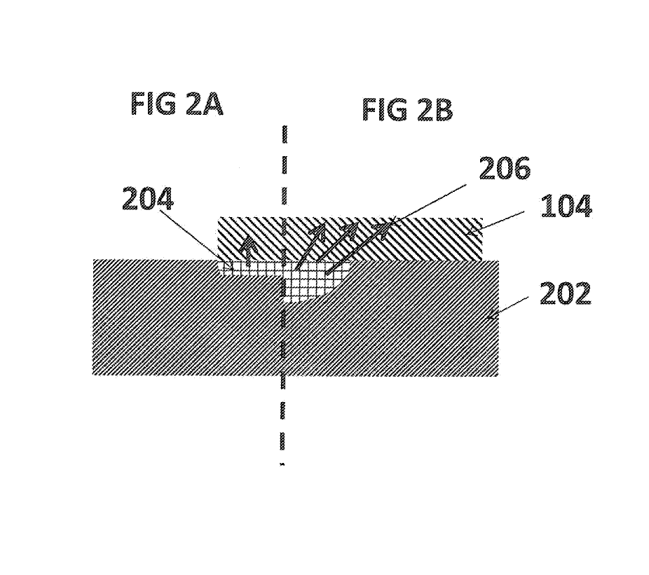

In various embodiments, the solar cell can have a substrate 202, wherein the dielectric layer 102 is configured on the substrate 202, and wherein the metal contacts 204 can be electrically connected (the dielectric layer 102 is not illustrated in FIG. 2 for sake of clarity) to the substrate 202 by the electrically conducting material in the openings 306.

The substrate 202 can have silicon or can be made therefrom.

While manufacturing the solar cell, for example, in a PERC solar cell process, the back of a Silicon-wafer-substrate 202 can be passivated in an electrically non-conducting manner by means of a dielectric layer 102.

The dielectric layer 102 can be configured structured, so that it has openings 306, for example, therefore, clearly in a single stage process. Alternatively, the openings 306 can be configured in a dielectric layer 102 after a complete forming of the dielectric layer 102, for example, therefore, clearly in a two stage process. For example, the dielectric layer 102 can be locally opened, i.e. the openings 306 can be configured by a Laser in a Laser process.

In an embodiment, a connection structure 302 (illustrated in FIG. 3 and FIG. 4) can be configured after forming the dielectric layer 102 with openings 306, for example, in a printing process.

For example, the connection structure 302 can be configured in the form of printed silver-solder-contacts.

After drying the printed silver-solder-contacts, a metallic coating can be configured on it. For example, aluminum from an aluminum particle containing paste (screen-printed paste) can be printed and dried on the connection structure 302.

Subsequently, the dried aluminum -coating can be burned (annealed) in a burning step. Therefore, the aluminum particle in the screen-printed paste can melt and silicon in the aluminum paste can be dissolved in the ablated areas in the aluminum coating in the openings 306 of the dielectric layer 102. The silicon-aluminum-mixture can be present as molten mass in the openings 306 of the dielectric layer 102. The percentage of the silicon, which can be dissolved in aluminum, can be temperature-dependent and is in a range of approximately 10% (mass %) (the molten area is indicated by the reference numerals 204 in FIG. 2A and FIG. 2B).

The silicon of the substrate 202 can diffuse (illustrated by means of arrows 206 in FIG. 2A and FIG. 2B) in the areas of the aluminum -coating surrounding the metal contacts 104. In a complete aluminum-coating, a relatively large volumes of aluminum is available for silicon, in which silicon can diffuse through the large boundaries of the ablated area. Thereby, a large amount of silicon can be dissolved into aluminum -metal contacts 104 without attaining the solubility limit. In other words: silicon of a silicon containing substrate 202 can diffuse in a large aluminum volume of aluminum containing metal contact 104. Accordingly, a lot of silicon can be dissolved in aluminum and the contact can be made deep accordingly. Thereby, a deeper trench can be etched in silicon, which is filled with a silicon/aluminum molten mass 204.

During cooling-off, the molten mass can flow out of the trenches (generally the openings 306) by poor wetting of the molten mass 204 on the substrate 202, whereby a cavity leaves behind.

In various embodiments, now the metal structure can be configured such that the amount of silicon—which can diffuse into aluminum-metal contact and the aluminum metal structure—is reduced. This can be facilitated, in which the metal contacts and the metal structure, i.e. for example, aluminum is configured only approximately in the exposed, for example, ablated area of the electrically non-conducting coating 104, for example, printed. Thereby, forming of cavities can be reduced or avoided. In other words: In various embodiments, the metal structure can be configured such that boundary between a respective opening 306 (and thereby the metal contact) and the surrounding (aluminum) metal structure is reduced such that the silicon diffusion into the area surrounding the openings is reduced. Thereby, silicon can diffuse only in a relatively small aluminum volume. The solubility-limit is attained quickly and the contact is not formed so deep. The risk of the cavity formation can be highly reduced. Furthermore, by preventing cavity formation, the series resistance can be reduced and the manufacture of the entire contact structure can be simplified, for example, with respect to a printing-process having several printing steps.

In various embodiments, the contact structure 300, 400 for double-faced solar cells can be configured (illustrated in FIG. 3A and FIG. 4A as schematic top view and FIG. 3B and FIG. 4B as schematic cross-sectional views).

In various embodiments, the metal contacts 104 are configured only in the opened areas of the dielectric layer 102. For example, an aluminum screen printing is done only in the ablated areas of the dielectric layer 102. In various embodiments, the transverse conductivity of the metal contacts 104 can be configured and/or increased by means of a connection structure 106. For example, the connection structure 106 can have (thin) copper wires of a so-called SmartWire interconnection or can be configured such. The connection structure 106 in these embodiments can be free from a metallic coating applied on the rear side of the solar cell.

In various embodiments, the solar cells rear side 300, 400 can have an additional connection structure 302, which is equipped with an external contact structure into an atomic fusion, for example, a solder connection. The additional connection structure 302 can be configured such that it can be configured more atomically fusible than the metal contacts 104 with respect to an external connection structure. The connection structure 302 can be soldered for making a solder connection with an external connection structure. The additional connection structure 302 can be configured at least electrically coupled with a portion of the contact area 102 (illustrated in FIG. 3A). The additional connection structure 302 can be configured, for example, electrically coupled (illustrated in FIG. 4A) at least to the portion of the metal contacts 104 through the connection structure 106. In an embodiment, the additional connection structure 302 can be configured electrically connected (illustrated in FIG. 3 and FIG. 4) at least to a portion of the connection structure 106. The additional connection structure 302 can be configured on or via the dielectric layer 102.

In an embodiment, the metal contacts 104 can have aluminum or can be made therefrom and the additional connection structure 302 can have silver or can be made therefrom, wherein silver is atomically more fusible (for example, solderable) than aluminum with respect to a contact structure. The additional connection structure 302 can have one of the following shapes: a number of connection lines (in a regular or irregular pattern) and/or a connecting grid. For example, the additional connection structure 302 can have at least one electrically conducting line-structure or an electrically conducting point-structure, for example, an electrically conducting solder point or adhesive point or can be configured therefrom. The additional connection structure 302 can be configured electrically conductive. The additional connection structure 302 can have a noble metal and/or a semi-noble metal, or can be made therefrom, for example, silver. For example, the additional connection structure 302 can have one of the following materials or can be made therefrom: aluminum, silver, copper, gold, zinc.

In various embodiments, the additional connection structure 302 can have a point-shaped additional connection structure 302 (illustrated in FIG. 3A) and/or a linear additional connection structure 302 (illustrated in FIG. 4A). For example, the additional connection structure 302 can have no silver surfaces (silver pads) (illustrated in FIG. 3A and FIG. 3B). In another embodiment (illustrated in FIG. 4A and FIG. 4B), the transverse conductivity can be configured by means of a connection structure 106, which has linear structures, for example, electrical Busbars (Busbars), for example, made of silver. The additional connection structure 302 can be configured on or via the connection structure 106. The additional connection structure 302 can have conventional solder strips and/or copper wires of the SmartWire interconnection. The additional connection structure 302 can be atomically fused to the networking structure 106, for example, glued-on or soldered, for example, in an electrically conducting manner The additional connection structure 302 can be configured—as described above—with an external connection structure to an atomic fusion of the solar cell rear side 300, 400. For example, the additional connection structure 302 can be configured parallel to the linear metal contacts 104 or ablated lines of the dielectric layer 102.

The additional connection structure 302 can have a lateral width in a range of approximately 10 μm to approximately 50 μm and a thickness in a range of approximately 2 μm to approximately a few millimetres, for example, 1 mm. In an embodiment, the linear additional connection structure 302 can be configured as the finger-shaped structure of the first electrode structure of the solar cell, for example, parallel, plano-parallel and/or congruent.

In various embodiments, the solar cell can have a diffusion bather between the substrate 202 and the electrically conductive material such that an inter-diffusion of the materials of the substrate 202 and electrically conductive material is reduced with respect to a contact without diffusion bather. For example, the diffusion bather can have a metal oxide or can be made therefrom, for example, as a native oxide coating.

A solar cell is provided in various embodiments, by which it is possible to reduce the diffusion of silicon in surrounding aluminum. Furthermore, series resistance losses can be reduced in solar cells.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A solar cell, comprising:
a substrate with a light incidence side and a rear side;
a dielectric layer on the back of the substrate, wherein the dielectric layer includes openings, which extend through the dielectric layer towards the back of the substrate;
a plurality of metal contacts which are configured in the openings; and
a metal structure which is configured on the dielectric layer;
wherein the metal structure includes contact areas which are connected to the metal contacts in an electrically conducting manner;
wherein the metal structure is structured such that the dielectric layer is at least partially exposed around the metal contacts.

2. The solar cell of claim 1,
wherein the metal structure includes at least one of the following materials:
silver;
zinc; and
aluminum.

3. The solar cell of claim 1,
wherein the plurality of metal contacts include aluminum.

4. The solar cell of claim 1,
wherein the metal structure includes a metallic coating configured on the dielectric layer.

5. The solar cell of claim 4,
wherein the metallic coating is a screen-printed coating.

6. The solar cell of claim 1,
wherein the metal structure includes several metal wires, which are connected to the metal contacts in an electrically conducting manner.

7. The solar cell of claim 1,
wherein the metal wires include copper.

8. The solar cell of claim 1,
wherein the metal structure includes several busbars, which are connected to the metal contacts in an electrically conducting manner.

9. The solar cell of claim 1,
wherein the metal contacts are configured such that the lateral expansion of a respective metal contact is limited to the lateral expansion of an associated opening.

10. The solar cell of claim 1,
wherein the exposed areas of the dielectric layer laterally surround the openings.

11. The solar cell of claim 1,
wherein the contact areas include an electrically conducting connection structure, which extends on the exposed areas of the dielectric layer up to the electrically conducting connections of the metal contacts with a metallic coating.

12. The solar cell of claim 11,
wherein the electrically conducting connection structure includes a grid-like structure.

13. The solar cell of claim 11,
wherein the electrically conducting connection structure includes the same material as the metal structure or the plurality of metal contacts.

14. The solar cell of claim 11,
wherein the electrically conducting connection structure includes one or more of the following metals:
aluminum;
silver;
copper;
zinc; and
gold.

15. A solar cell module, comprising:
a plurality of solar cells, each solar cell comprising:
a substrate with a light incidence side and a rear side;
a dielectric layer on the back of the substrate, wherein the dielectric layer includes openings, which extend through the dielectric layer towards the back of the substrate;
a plurality of metal contacts which are configured in the openings; and
a metal structure which is configured on the dielectric layer;
wherein the metal structure includes contact areas which are connected to the metal contacts in an electrically conducting manner;
wherein the metal structure is structured such that the dielectric layer is at least partially exposed around the metal contacts;
wherein the plurality of solar cells are interconnected in an electrically conducting manner.
